(19) United States
(12) Patent Application Publication
(10) Pub. No.: US 2009/0078459 A1
(43) Pub. Date: Mar. 26, 2009

(54) LIGHT-TRANSMITTING CONDUCTIVE FILM AND PROCESS FOR PRODUCING LIGHT-TRANSMITTING CONDUCTIVE FILM

(75) Inventor: Ryo Nishizakura, Kanagawa (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 11/908,628

(22) PCT Filed: Mar. 14, 2006
(86) PCT No.: PCT/JP2006/305054

§ 371 Date: Sep. 14, 2007

(30) Foreign Application Priority Data
Mar. 15, 2005 (JP) 2005-073050

(51) Int. Cl. H05K 9/00; B32B 3/10; G03F 7/20

(52) U.S. Cl. 174/389; 428/209; 430/311

(57) ABSTRACT

To provide a process which can produce an electromagnetic wave-shielding material having both high light-transmitting properties and sufficient EMI-shielding properties and forming no moiré, which facilitates formation of a fine-line pattern and which can produce the material inexpensively on a large scale. In particular, to provide a process for producing a light-transmitting electromagnetic wave-shielding film.

A light-transmitting conductive film comprising a transparent support having provided thereon a mesh constituted by conductive metal portions and visible light-transmitting portions, wherein the mesh pattern continuously extends 3m or longer and are formed by exposure and development of a silver halide light-sensitive material to form metal portions having electrical conductivity, with the electrical conductivity being more enhanced by physical development.

### TECHNICAL FIELD

The present invention relates to a light-transmitting conductive film and a process for producing the light-transmitting conductive film. The light-transmitting conductive film is used as an electromagnetic wave shielding film which shields electromagnetic waves generated from the display front surface of CRT (cathode ray tube), PDP (plasma display panel), liquid crystal, EL (electroluminescence), FED (field emission display) or the like, or from a microwave oven, an electronic device, a printed wiring board or the like and which has transparent properties.

Also, the light-transmitting conductive film is used for a semiconductor element for photographing as well as these image display devices.

### BACKGROUND ART

In recent years, with the increase of use of various electric equipment and electro-applied equipment, electromagnetic interference (EMI) has sharply increased. EMI can be the cause of erroneous operation and troubles of electronic or electric devices and, further, is pointed out to cause health troubles to operators of these devices. Therefore, electronic or electric devices are required to suppress the intensity of radiation of electromagnetic wave within the level of the standard or regulation.

In order to take countermeasures for the above-mentioned EMI, it is necessary to shield electromagnetic wave and, for this purpose, it is self-evident that it suffices to utilize the properties of metals of not penetrating electromagnetic wave. For example, there have been employed a method of making a housing from a metal or a highly dielectric material, a method of inserting a metal plate between circuit substrates and a method of covering a cable with a metal foil. With CRT, PDP, etc., however, it is necessary for an operator to recognize letters or the like displayed on the screen, and hence transparency in display is required. Therefore, all of the aforesaid methods wherein the display front surface is often opaque have been inadequate as methods for shielding electromagnetic wave.

In particular, in comparison with CRT or the like, PDP generates more electromagnetic wave and is required to have stronger electromagnetic wave-shielding ability. The electromagnetic wave-shielding ability can simply be represented in terms of a surface resistivity value. While a surface resistivity value of about 300 Ω/sq or less is required for a light-transmitting electromagnetic wave-shielding material for use in CRT, a surface resistivity value of 2.5 Ω/sq or less is required for a light-transmitting electromagnetic wave-shielding material for use in PDP and, with a plasma TV set for consumer use using DP, there exists high necessity for a surface resistivity value of 1.5 Ω/sq or less and, more desirably, there exists a demand for an extremely high electrical conductivity as low as 0.1 Ω/sq or less.

Also, regarding the level for transparency, a transparency of about 70% or more is required for CRT use, and a transparency of 80% or more is required for PDP use, with a much higher transparency being desired for both.

In order to solve the above-mentioned problems, there have so far been proposed, as shown hereinafter, various materials and methods which can provide both necessary electromagnetic wave-shielding properties and necessary transparency utilizing a metal mesh having openings, for example, a shielding material formed of a mesh of conductive fibers, a method of printing an electroless plating catalyst in a lattice pattern according to a printing method and conducting electroless plating on the pattern, a method of forming an electroless plating catalyst-containing photoresist in a mesh-like pattern and conducting electroless plating on the pattern, and a method of forming a mesh of a metal thin film by etching according to a photolithography technique. These methods, however, involve such problem as that the production steps are intricate and complicated and lead to expensive production cost, that line width becomes non-uniform at the intersection points of the lattice pattern, that moiré is generated or that one or both of light-transmitting properties and conductive properties become insufficient, thus having been desired to be improved.

As a means for solving the problems, there has been proposed a method of forming an conductive metal silver pattern by using a silver salt.

Silver salt light-sensitive materials have conventionally been popularly be used mainly as materials for recording or transmitting images or pictures such as photographic films (e.g., color negative films, black-and-white negative films, films for cinema, color reversal films, etc.), photographic printing papers (e.g., color paper, black-and-white photographic paper, etc.) and, further, an emulsion mask (photo mask) utilizing formation of metal silver in conformity with an exposed pattern. With these, images themselves obtained by exposing and developing a silver salt have a value, and images per se have been utilized for a long period of time since birth of the light-sensitive materials.

However, although being out of the values as images, developed silver obtained from a silver salt is metal silver, and hence electrical conductivity of the metal silver can be utilized depending upon its production process. Thus, proposals of utilizing it from such standpoint have long been found here and there. As an example of disclosing a method of specifically forming an conductive silver film, JP-B-42-23746 (the term “JP-B” as used herein means an “examined Japanese patent application”) discloses in the 1960s a method of forming a metal silver thin film pattern according to a silver salt diffusion transfer technique of depositing silver on physically developing nuclei. Also, JP-B-43-12862 discloses that a uniform silver thin film with no light-transmitting properties obtained by utilizing similar silver salt diffusion transfer technique has the ability of attenuating microwave. Analytical Chemistry, vol. 72, p 645 (2000) and WO01/51276 describe a method of forming an conductive pattern by simply conducting exposure and development employing this principle as such and using an instant black-and-white slide film. In addition, JP-A-2001-149773 (the term “JP-A” as used herein means an “unexamined published Japanese patent application”) describes a method of forming an conductive silver film which can be utilized as a display electrode for use in plasma display.

However, an conductive metal silver film obtained by these methods has insufficient light-transmitting properties for image display or for use in image-forming elements and an insufficient ability for shielding electromagnetic wave irradiated from an image display surface of a display such as CRT or PDP without inhibiting image display.

It has also been difficult to obtain high electrical conductivity and, when it is intended to obtain a thick silver film in order to obtain high electrical conductivity, there arises a problem of spoiled transparency. Therefore, employment of the above-mentioned silver salt diffusion transfer method as such has failed to provide a light-transmitting and electromagnetic wave-shielding material having excellent light-transmitting properties and excellent electrical conductivity adequate for shielding electromagnetic wave from the image display surface of an electronic display device.

Also, in the case of imparting electrical conductivity through the steps of development, physical development and plating utilizing common commercially available negative film without employing the silver salt diffusion transfer method, only insufficient electrical conductivity and transparency as a light-transmitting and electromagnetic wave-shielding material for CRT or PDP have been obtained.

In order to solve the above-mentioned problems, several methods have been proposed. JP-A-2004-221564 proposes a process for producing a light-transmitting and electromagnetic wave-shielding material by forming a pattern through development using a silver salt light-sensitive material and then subjecting the material to plating or physical development treatment. A light-transmitting conductive film prepared by utilizing a photographic light-sensitive material using a silver salt as in this method has advantages of high transparency and inexpensive mass production cost in comparison with other methods since fine patterns can be formed with accuracy. However, in the case of imparting electrical conductivity by plating, blackening processing is required in order to obtain contrast of PDP. Besides, use of the metal mixture imposes large environmental load. In the case of imparting electrical conductivity by physical development, the physical development requires such a long period of time that unnecessary silver is liable to precipitate in visible light-transmitting portions. Therefore, it has still been insufficient to obtain both transparency and electrical conductivity, and solution of these problems has been desired.

### DISCLOSURE OF THE INVENTION

### Problems that the Invention is to Solve

As is described in the aforesaid patent document 5, comparatively good electrical conductivity can be obtained by subjecting a silver salt light-sensitive material to physical development and/or plating. In the case of performing plating, however, contrast of FDP is reduced due to the color of plated metal, thus a step of blackening processing being required. Also, there is involved the problem that the film is yellowed due to metal plating when left for a long period under the conditions of high temperature and high humidity. Further, since the plating forms a metal mixture of the plating metal and silver, there has been the problem that reproduction of the material requires more procedures. In the case of conducting physical development, a long-time physical development is required in order to obtain sufficient electrical conductivity, which tends to precipitate unnecessary silver in light-transmitting portions, and thus there has been the problem of reduced light-transmitting properties.

The invention is made in consideration of these circumstances, and an object of the invention is to provide a process capable of producing an electromagnetic wave shielding material which has high light-transmitting properties and, at the same time, sufficient EMI-shielding properties with forming no moiré, which facilitates formation of a fine-line pattern and which can be produced inexpensively on a large scale. Another object of the invention is to provide a light-transmitting and electromagnetic wave-shielding film obtainable by the above-mentioned production process.

### Means for Solving the Problems

As a result of intensive investigations in view of obtaining both high EMI-shielding properties and high transparency at the same time, the inventors have found that the above-described objects can effectively be attained by the following production process and light-transmitting and electromagnetic wave-shielding film, thus having completed the invention.

That is, the objects of the invention are attained by the following production process.

(1) An light-transmitting conductive film comprising a transparent support having provided thereon a 3-m or longer continuous mesh pattern constituted by conductive metal portions and visible light-transmitting portions, which is obtained by mesh pattern-wise exposing a silver halide light-sensitive material and then subjecting the material to physical development to thereby more enhance electrical conductivity.
(2) The light-transmitting conductive film as described in (1) described above, which is obtained by development processing using a developing solution having an oxidation-reduction potential less noble than −290 mV.
(3) The light-transmitting conductive film as described in (1) or (2) described above, wherein the conductive metal silver portions are formed in a mesh pattern of 20 μm or less in line width, with the mesh opening ratio and the mesh surface resistivity being 80% or more and 5 Ω/sq or less, respectively.
(4) The light-transmitting conductive film as described in any one of (1) to (3) described above, wherein the conductive metal silver portions are formed in a mesh pattern of 20 μm or less in line width, with the mesh opening ratio and the mesh surface resistivity being 80% or more and 1 Ω/sq or less, respectively.
(5) The light-transmitting conductive film as described in any one of (1) to (4) described above, wherein the volume resistivity of the conductive metal is from 1.6 to 100 Ωcm.
(6) The light-transmitting conductive film as described in any one of (1) to (5) described above, which is obtained from a silver halide light-sensitive material comprising a support having provided thereon a silver-containing layer of 1/3 or more in Ag/binder ratio by volume.
(7) The light-transmitting conductive film as described in any one of (1) to (6) described above, wherein the conductive metal portions are black.
(8) A process for producing a light-transmitting conductive film, which comprises exposing a silver halide light-sensitive material comprising a transparent support having provided thereon a silver halide light-sensitive layer, subjecting the material to development processing to form a 3-m or longer continuous mesh pattern composed of conductive metal portions and visible light-transmitting portions, and then subjecting the material to physical development to thereby more enhance electrical conductivity.
(9) The process for producing the light-transmitting conductive film as described in (8) described above, wherein the development processing is conducted using a developing solution having an oxidation-reduction potential less noble than −290 mV.
(10) The process for producing the light-transmitting conductive film as described in (8) or (9) described above, wherein the physical development is conducted in a solution of dissolution physical development containing a soluble silver complex salt and a reducing agent.
(11) The process for producing the light-transmitting conductive film as described in (8) or (9) described above, wherein the physical development is conducted in a physically developing solution containing a soluble silver complex salt-forming agent, a reducing agent and silver ion.
(12) Alight-transmitting and electromagnetic wave-shielding film for a plasma display panel, which contains the light-transmitting conductive film described in any one of (1) to (7) described above.
(13) A plasma display panel having the light-transmitting and electromagnetic wave-shielding film described in (12) described above.

### ADVANTAGES OF THE INVENTION

According to the production process of the invention, there can be provided a light-transmitting conductive film which has both high electrical conductivity and high transparency at the same time and wherein the mesh portions are black. Also, according to the invention, there can be provided a process for producing a light-transmitting conductive film which enables one to form a fine-lined pattern in short steps and which can produce a light-transmitting conductive film in a role form which film has both high electrical conductivity and high transparency at the same time and wherein the mesh portions are black.

### BEST MODE FOR CARRYING OUT THE INVENTION

The light-transmitting conductive film of the invention, light-transmitting and electromagnetic wave-shielding film of the invention and processes of the invention for their production will be described in detail hereinafter.

### (Light-Sensitive Material)

### (Support)

As a support in the light-sensitive material to be used in the production process of the invention, a plastic film, plastic plate, glass plate, and the like can be used.

As materials for the above-mentioned plastic film and plastic plate, there can be used, for example, polyesters such as polyethylene terephthalate (PET) and polyethylene naphthalate; polyolefins such as polyethylene (PE), polypropylene (PP), polystyrene and EVA; vinyl series resins such as polyvinyl chloride and polyvinylidene chloride; and others such as polyether ether ketone (PEEK), polysulfone (PSF), polyether sulfone (PES), polycarbonate (PC), polyamide, polyimide, acrylic resin and triacetyl cellulose (TAC).

In the invention, the above-mentioned plastic film is preferably polyethylene terephthalate film and/or triacetyl cellulose (TAC) in view of transparency, heat resistance, easy handling and price.

Since transparent properties are required for electromagnetic wave shielding materials for use in displays, high transparency is desired for the support. In such cases, the total visible light transmittance of a plastic film or a plastic plate is preferably from 70 to 100%, more preferably from 85 to 100%, particularly preferably from 90 to 100%. Also, in the present invention, plastic films or plastic plates colored to a degree of not inhibiting to attain the objects of the invention can be used as the above-described plastic films or plastic plates.

The plastic film and plastic plate in the present invention may be used as a single layer, but may be used as a multi-layer film wherein two or more layers thereof are combined with each other.

In the case of using a glass plate as the support in the present invention, its kind is not particularly limited. However, in the case of using for an electromagnetic wave shielding film for a display, it is preferred to use a tempered glass plate having a tempered layer on the surface thereof. In comparison with glass plates not having been subjected to tempering treatment, the tempered glass plate has a higher possibility of being able to resist breakage. Further, if broken by any chance, the tempered glass plate obtained by an air-cooling method is broken into fine pieces with non-sharp fractured surface, thus being preferred in view of safety.

### (Protective Layer)

A light-sensitive material to be used may have a protective layer on an emulsion layer to be described hereinafter. In the present invention, the phrase “protective layer” means a layer comprising a binder such as gelatin or a high-molecular polymer and is formed on an emulsion layer having light sensitivity in order to provide the effects of preventing scratches and improving dynamic properties. In view of conducting physical development, it is preferred not to provide the protective layer and, if provided, a smaller thickness is preferred. The thickness is preferably 0.2 μm or less. Methods for coating the protective layer are not particularly limited, and a known coating method may properly be selected.

Additionally, the light-sensitive material to be used in the production process of the present invention may contain a known dye in the emulsion layer for the purpose of dyeing or the like.

### (Emulsion Layer)

The light-sensitive material to be used in the production process of the present invention preferably has on the support thereof an emulsion layer (silver salt-containing layer) containing a silver salt as a photo sensor. In the emulsion layer in the invention may be incorporated, as needed, a dye, binder, solvent, etc. in addition to the silver salt.

### (Dyes)

The light-sensitive material may contain a dye at least in an emulsion layer. The dye is incorporated in the emulsion layer as a filter dye or for other various purposes such as prevention of irradiation. As the dyes, solid disperse dyes may be incorporated. As dyes to be preferably used in the invention, there are illustrated dyes represented by the general formulae (FA), (FA1), (FA2) and (FA3) described in JP-A-9-179243. Specifically, compounds F1 to F34 described in the official gazette are preferred. Also, (II-2) to (II-24) described in JP-A-7-152112, (III-5) to (III-18) described in JP-A-7-152112, (IV-2) to (IV-7) described in JP-A-7-152112, and the like are preferably used.

As further dyes which can be used in the present invention, there are illustrated cyanine dyes, pyrylium dyes and aluminum dyes described in JP-A-3-138640 as dyes in a solid, finely particulate dispersed state which are to be decolored upon development or fixing processing. Also, as dyes which are not decolored upon processing, there are illustrated carboxyl group-having cyanine dyes described in JP-A-9-96891, acidic group-free cyanine dyes described in JP-A-8-245902, lake type cyanine dyes described in JP-A-8-333519, cyanine dyes described in JP-A-1-266536, holopolar type cyanine dyes described in JP-A-3-136038, pyrylium dyes described in JP-A-62-299959, polymer type cyanine dyes described in JP-A-7-253639, solid fine particle dispersions of oxonol dyes described in JP-A-2-282244, light-scattering particles described in JP-A-63-131135, Yb3+ compounds described in JP-A-9-5913 and ITO powder described in JP-A-7-113072. Further, dyes represented by the general formulae (F1) and (F2) described in JP-A-9-179243, specifically compounds F35 to F112 described in JP-A-9-179243 can be used as well.

Also, as the above-mentioned dyes, water-soluble dyes can be incorporated. As such water-soluble dyes, oxonol dyes, benzylidene dyes, merocyanine dyes, cyanine dyes and azo dyes are illustrated. Of these, oxonol dyes, hemioxonol dyes and benzylidene dyes are useful in the present invention. As specific examples of the water-soluble dyes which can be used in the present invention, there are illustrated those dyes which are described in BP No. 584,609, BP No. 1,177,429, JP-A-48-85130, JP-A-49-99620, JP-A-49-114420, JP-A-52-20822, JP-A-59-154439, JP-A-59-208548, U.S. Pat. Nos. 2,274,782, 2,533,472, 2,956,879, 3,148,187, 3,177,078, 3,247,127, 3,540,887, 3,575,704, 3,653,905 and 3,718,427.

The content of the dye in the emulsion layer is preferably from 0.01 to 10% by weight, more preferably from 0.1 to 5% by weight, based on the weight of the entire solid components in view of the irradiation-preventing effect and sensitivity reduction due to an increase in the amount of added dyes.

### (Silver Salts)

As silver salts to be used in the present invention, there are illustrated inorganic silver salts such as silver halide. In the present invention, use of a silver halide having excellent properties as photo sensor is preferred Silver halide to be preferably used in the present invention is described below.

In the present invention, it is preferred to use silver halide so as to function as a photo sensor, and technologies related to silver halide and employed for silver salt photographic films, photographic printing paper, films for making a printing plate and emulsion masks for photo mask can also be employed in the present invention.

The halogen elements contained in the silver halide may be any of chlorine, bromine, iodine and fluorine or may be a combination thereof. For example, silver halides containing AgCl, AgBr or AgI as a major component are preferably used, with silver halides containing AgBr or AgCl as a major component being more preferably used. Silver chlorobromide, silver chloroiodide and silver iodobromide are preferably used as well. Silver chlorobromide, silver bromide, silver iodochlorobromide and silver iodobromide are more preferred, and silver chlorobromide and silver iodochlorobromide containing 50 mol % or more silver chloride are most preferably used.

Additionally, the phrase “silver halides containing AgBr (silver bromide) as a major component” as used herein means silver halides wherein mol fraction of bromide ion in the silver halide formulation accounts for 50% or more. The silver halide grains containing AgBr as a major component may further contain iodide ion or chloride ion in addition to bromide ion.

Silver halide is in a solid particulate state and, in view of image quality of a pattern-like metal silver layer formed after exposure and development processing, the average particle size of silver halide is preferably from 0.1 to 5,000 nm (5 μm) in terms of equivalent-sphere diameter.

Additionally, the equivalent-sphere diameter of silver halide grains is a diameter of a spherical particle having the same volume.

The silver halide grains are not particularly limited as to their shapes, and they may be in various forms such as a spherical form, cubic form, tabular form (hexagonal tabular, trigonal tabular or tetragonal tabular), octahedral form or tetradecahedral form, with a cubic form or a tetradecahedral form being preferred.

The inner portion and the surface layer of silver halide grains may comprise a uniform phase or different phases. Also, the silver halide grains may have localized layers, which have different compositions, in the interior or the surface of the grains.

A silver halide emulsion which is a coating solution for an emulsion layer to be used in the present invention can be prepared by using processes described in Chimie et Physique Photographique written by P. Glafkides (published by Paul Montel Co. in year 1967), Photographic Emulsion Chemistry written by G. F. Dufin (published by The Focal Press in year 1966), Making and Coating Photographic Emulsion written by V. L. Zelikman et al. (published by The Focal Press in year 1964), and the like.

That is, as a process for preparing the above-mentioned silver halide emulsion, any of an acidic process, a neutral process, etc. may be employed. As a method of reacting a soluble silver salt with a soluble halogen salt, any of a one-side mixing method, a simultaneous mixing method, a combination thereof, etc. may be employed.

As a method for forming silver grains, a method of forming grains in the presence of an excess of silver ion (so-called reverse mixing method) may be employed. Further, as one type of the simultaneous mixing methods, a method of keeping pAg at a constant level in the liquid phase wherein silver halide is generated, i.e., a so-called controlled double jet method may also be employed.

It is also preferred to form grains by using a so-called silver halide solvent such as ammonia, thioether, tetra-substituted thiourea or the like. As such methods, a method of using a tetra-substituted thiourea compound is preferred, which is described in JP-A-53-82408 and JP-A-55-77737. Preferred thiourea compounds include tetramethylthiourea and 1,3-dimethyl-2-imidazolidinethione. The addition amount of the silver halide solvent varies depending upon kinds of used compounds, intended grain sizes and formulation of halides, but is preferably from 10⁻⁵ to 10⁻² mol per mol of silver halide.

The above-mentioned controlled double jet method and the grain-forming method using a silver halide solvent facilitate to prepare a silver halide emulsion wherein crystal form is regular and particle size distribution is narrow, thus being preferably used in the present invention.

Also, in order to unify the particle size, it is preferred to cause quick growth of silver grains within a range of not exceeding the critical saturation degree by employing a method of changing the rate of adding silver nitrate or alkali halide in accordance with the growth rate of grains as described in BP 1,535,016, JP-B-48-36890 and JP-B-52-16364 or a method of changing the concentration of the aqueous solution a described in BP 4,242,445 and JP-A-55-158124. The silver halide emulsion to be used for forming an emulsion layer in the present invention, a mono-disperse emulsion is preferred, with the coefficient of variation represented by ({standard deviation of grain size)/(average grain size)}×100 being 20% or less, more preferably 15% or less, most preferably 10% or less.

The silver halide emulsion to be used in the invention may be a mixture of plural kinds of silver halide emulsions different from each other in grain size.

The silver halide emulsion to be used in the invention may contain a metal belonging to the group VIII or VIIB. In particular, in order to obtain high contrast and low fog, it is preferred to incorporate a rhodium compound, an iridium compound, a ruthenium compound, an iron compound, an osmium compound, a rhenium compound, etc. These compounds may be compounds having various ligands and, as such ligands, there can be illustrated cyanide ion, halide ion, thiocyanato ion, nitrosyl ion, water, hydroxide ion, etc. and, in addition to these pseudo halides and ammonia, organic molecules such as an amine (e.g., methylamine or ethylenediamine), a hetero ring compound (e.g., imidazole, thiazole, 5-methylthiazole or mercaptoimidazole), urea and thiourea.

Further, in order to enhance sensitivity, doping with a hexacyano-metal complex such as K₄[Fe(CN)₆] or K₃[Cr(CN)₆] is advantageously effected.

As the above-described rhodium compounds, water-soluble rhodium compounds can be used. Examples of the water-soluble rhodium compounds include rhodium (III) halide compounds, hexachlororhodium (III) complex salts, pentachloroaquorhodium complex salts, tetrachlorodiaquorhodium complex salts, hexabromorhodium (III) complex salts, hexaaminerhodium(III) complex salts, trioxalatorhodium (III) complex salts and K₃Rh₂Br₉.

These rhodium compounds are used after dissolving them in water or an appropriate solvent, and a method commonly used for stabilizing the rhodium compound solution, that is, a method comprising adding an aqueous solution of hydrogen halogenide (e.g., hydrochloric acid, hydrobromic acid or hydrofluoric acid) or halogenated alkali (e.g., KCl, NaCl, KBr or NaBr) may be employed. In place of using a water-soluble rhodium compound, separate silver halide grains previously doped with rhodium may be added and dissolved at the time of preparation of silver halide.

Examples of the iridium compounds include hexachloroiridium complex salts such as K₂IrCl₆ and K₃IrCl₆, hexabromodiridium complex salts, hexaanminiridium complex salts and pentachloronitrosyliridium complex salts.

Examples of the ruthenium compounds include hexachlororuthenium, pentachloronitrosylruthenium and K₄[Ru(CN)₆].

Examples of the iron compounds include potassium hexacyanoferrate (II) and ferrous thiocyanate.

Ruthenium and osmium described above are added in the form of water-soluble complex salts described in JP-A-63-2042, JP-A-1-285941, JP-A-2-20852, JP-A-2-20655, etc. and, as particularly preferred ones, 6-ligand complexes represented by the following formula are illustrated.

[ML₆]⁻ⁿ

(In the above formula, M represents Ru or Os, and n represents 0, 1, 2, 3 or 4.)

In this case, the counter ion is of no importance and, for example, ammonium or alkali metal ion is used. Examples of preferred ligands include a halide ligand, a cyanide ligand, a cyanate ligand, a nitrosyl ligand and a thionitrosyl ligand. Specific examples of the complexes to be used in the present invention are illustrated below which, however, do not limit the present invention in any way.

[RuCl₆]⁻³, [RuCl₄(H₂O)₂]⁻¹, [RuCl₅(NO)]⁻², [RuBr₅(NS)]⁻², [Ru(CO)₃Cl₃]⁻², [Ru(CO)Cl₅]⁻², [Ru(CO)Br₅]⁻², [OsCl₆]⁻³, [OsCl₅(NO)]⁻², [Os(NO)(CN)₅]⁻², [Os(NS)Br₅]⁻², [Os(CN)₆]⁻⁴, [Os(O)₂(CN)₅]⁻⁴.

The addition amounts of these compounds are preferably from 10⁻¹⁰ to 10⁻² mol/mol Ag, more preferably from 10⁻⁹ to 10⁻³ mol/mol Ag, per mol of silver halide.

Besides, silver halide containing Pd(II) ion and/or a Pd metal can also be preferably used in the present invention. Pd may uniformly be distributed within silver halide grains, but is preferably incorporated in the vicinity of the surface layer of silver halide grains. Here, the phrase “incorporated in the vicinity of the surface layer of silver halide grains” means that the silver halide grains have, within 50 nm in the depth direction from the surface of the grains, a layer containing palladium in a higher content than in other layers.

Such silver halide grains can be prepared by adding Pd in the course of forming silver halide grains. It is preferred to add Pd after adding 50% or more of the total amounts of silver ion and halide ion, respectively. It is also preferred to allow Pd(II) ion to exist in the surface layer of silver halide by a method of, for example, adding Pd(II) ion upon post-ripening.

The Pd-containing silver halide grains accelerate physical development or electroless plating, increases efficiency of production of desired electromagnetic wave shielding materials, and contribute to reduction of production cost. Pd is well known a catalyst for electroless plating. In the present invention, Pd can be localized in the surface layer of silver halide grains, which enables one to save extremely expensive Pd.

In the present invention, the content of Pd ion and/or Pd metal to be incorporated in silver halide is preferably from 10⁻⁴ to 0.5 mol/mol Ag, more preferably from 0.01 to 0.3 mol/mol Ag, per mol of silver.

Examples of the Pd compound to be used include PdCl₄ and Na₂PdCl₄.

Further, in the present invention, in order to more improve sensitivity as a photo sensor, silver halide emulsions may be subjected to chemical sensitization which is conducted for photographic emulsions. As methods of chemical sensitization, chalcogen sensitization such as sulfur sensitization, selenium sensitization or tellurium sensitization, noble metal sensitization such as gold sensitization, reduction sensitization, etc. can be employed. These are used independently or in combination. In the case of using the chemical sensitization methods in combination, for example, a combination of the sulfur sensitization method and the gold sensitization method, a combination of the sulfur sensitization method, the selenium sensitization method and the gold sensitization method, and the combination of the sulfur sensitization method, the tellurium sensitization method and the gold sensitization method are preferred.

The sulfur sensitization is usually conducted by adding a sulfur sensitizing agent and stirring the emulsion for a predetermined period at a high temperature of 40° C. or above. As the sulfur sensitizing agent, known compounds may be used. For example, sulfur compounds contained in gelatin and, in addition, various sulfur compounds such as thiosulfates, thioureas, thiazole and rhodanine can be used. Preferred sulfur compounds are thiosulfates and thiourea compounds. The addition amount of the sulfur sensitizing agent varies depending upon various factors such as pH and temperature upon chemical ripening and the size of silver halide grains, and is preferably from 10⁻⁷ to 10⁻² mol, more preferably from 10⁻⁵ to 10⁻³ mol, per mol of silver halide.

As the selenium sensitizing agent to be used for the selenium sensitization, known selenium compounds can be used. That is, the selenium sensitization can usually be conducted by adding a labile type and/or non-labile type selenium compound and stirring the emulsion for a definite period at a high temperature of 40° C. or above. As the labile type selenium compound, compounds described in JP-B-44-15748, JP-B-43-13489, JP-A-4-109240, JP-A-4-324855, etc. can be used. In particular, use of compounds represented by the general formulae (VIII) and (IX) described in JP-A-4-324855 is preferred.

The tellurium sensitizing agent to be used as the above-mentioned tellurium sensitizing agent is a compound which can generate silver telluride, assumed to constitute sensitizing nuclei, on the surface or in the interior of silver halide grains. The rate of generation of silver telluride in a silver halide emulsion can be determined by the test according to the method described in JP-A-5-313284. Specifically, those compounds can be used which are described in U.S. Pat. Nos. 1,623,499, 3,320,069 and 3,772,031, BP Nos. 235,211, 1,121,496, 1,295,462, 1,396,696, Canadian Patent No. 800,958, JP-A-4-204640, JP-A-4-271341, JP-A-4-333043, JP-A-5-303157, Journal of Chemical Society Chemical Communication (J. Chem. Soc. Chem. Commun.), p. 635 (1980), ibid., p. 1102 (1979), ibid., p. 645 (1979), Journal of Chemical Society Perkin Transaction (J. Chem. Soc. Perkin. Trans.), vol. 1, p. 2191 (1980), The Chemistry of Organic Selenium and Tellurium Compounds compiled by S. Patai, vol. 1 (1986) and ibid., vol. 2 (1987). In particular, compounds represented by the general formulae (II), (III) and (IV) in JP-A-5-313284 are preferred.

The amounts of the selenium sensitizing agent and the tellurium sensitizing agent which can be used in the present invention vary depending upon silver halide grain size used and chemically ripening conditions, but are generally from about 10⁻⁸ to about 10⁻² mol, preferably from about 10⁻⁷ to about 10⁻³ mol, per mol of silver halide. The chemically sensitizing conditions in the present invention are not particularly limited, but the pH is from 5 to 8, pAg is from 6 to 11, preferably from 7 to 10, and the temperature is from 40 to 95° C., preferably from 45 to 85° C.

Also, as the noble metal sensitizing agent, there are illustrated gold, platinum, palladium, iridium, etc., with gold sensitization being particularly preferred. As the specific gold sensitizers to be used for the gold sensitization, there are illustrated chloroauric acid, potassium chloroaurate, potassium aurithiocyanate, gold sulfide, gold (I) thioglucose, gold (I) thiomannose, etc. They can be used in an amount of from about 10⁻⁷ to about 10⁻² mol per mol of silver halide. In the silver halide emulsion to be used in the invention, a cadmium salt, sulfite salt, lead salt, thallium salt or the like may be allowed to coexist in the course of formation or physical ripening of silver halide grains.

Also, in the invention, reduction sensitization can be employed. As the reduction sensitizers, stannous salts, amines, formamidinesulfinic acid, silane compounds, etc. can be used. To the above-mentioned silver halide emulsion may be added a thiosulfonic acid compound according to the method described in European Unexamined Patent Publication (EP) No. 293917. As silver halide emulsions to be used for preparing the light-sensitive material to be used in the present invention, one kind thereof, or a combination of two or more kinds thereof (for example, a combination of silver halide emulsions different from each other in average grain size, halide composition, crystal habit, conditions for chemical sensitization or in sensitivity) may be used. In particular, in order to obtain high contrast, it is preferred to coat an emulsion having a higher sensitivity in a position nearer to the support as described in JP-A-6-324426.

### (Exposure)

In the present invention, exposure of a silver halide-containing layer provided on a support is conducted.

Exposure can be conducted by using electromagnetic wave. Examples of the electromagnetic wave include lights such as visible light and ultraviolet rays and radiation such as X rays Further, a light source having a wavelength distribution may be utilized for the exposure, or a light source of a particular wavelength may be used.

As the light source, there can be illustrated, for example, scan exposure using a cathode ray tube (CRT). In comparison with an apparatus using a laser, the cathode ray tube exposure apparatus is simple and compact, thus serving to reduce the cost. In addition, it facilitates adjustment of optical axis or color. In the cathode ray tube to be used for imagewise exposure, various illuminants capable of emitting a light of a spectral region are used, as needed. For example, any one, or a combination of two or more, of a red light-emitting illuminant, a green light-emitting illuminant and a blue light-emitting illuminant is used. The spectral regions are not limited to the above-mentioned red, green and blue regions, and phosphors capable of emitting a yellow light, an orange light, a violet light or a light in the infrared region may also be used. In particular, a cathode ray tube which contains a mixture of these illuminants to emit a white light is often used. In addition, an Ultraviolet ray lamp is also preferred, and g-line radiation of a mercury lamp or i-line radiation of a mercury lamp is utilized as well.

In addition, in the present invention, exposure can be conducted by using various laser beams. For example, exposure in the present invention can preferably employs a scan exposure system using a mono-color, high-density light emitted from, for example, a gas laser, a light-emitting diode, a semi-conductor laser or a second harmonic generator (SHG) having a combination of a semi-conductor or a solid state laser using a semi-conductor laser as an exciting light source, and a non-linear optical crystal. Further, a KrF excimer laser, an ArF excimer laser, an F2 laser, etc. can be used as well. In order to make the system compact and inexpensive, exposure is preferably conducted by using a semi-conductor laser or a second harmonic generator (SHG) having a combination of a semi-conductor laser or a solid state laser. In particular, in order to design a compact and inexpensive apparatus having a long life and a high stability, it is preferred to conduct exposure by using a semi-conductor laser.

As a laser light source, specifically, a blue light-emitting semi-conductor capable of emitting a light of from 430 to 460 nm in wavelength (presented by Nichia Chemical Industries, Ltd. in the 48^{th} Oyo Butsurigaku Kankei Rengo Koenkai held in March, 2001), a green light-emitting laser emitting a light of about 530 nm in wavelength taken out by converting wavelength of a laser light (oscillation wavelength: about 1060 nm) with a SHG crystal of LiNbO₃ having a wave guide-shaped periodically inverted domain structure, a red light-emitting semi-conductor laser capable of emitting a light of about 685 nm in wavelength (Hitachi type No. HL6738MG), a red light-emitting semi-conductor laser capable of emitting a light of about 650 nm in wavelength (Hitachi type No. HL6501MG), and the like are preferably used.

The silver salt-containing layer may be pattern-wise exposed by surface exposure utilizing a photo mask or by scan exposure with a laser beam. In this case, exposure may be refraction type exposure using a lens or a reflection type exposure using a reflection mirror and, regarding exposure system, contact exposure, proximity exposure, projection exposure in a reduced size, reflection-type projection exposure or the like may be employed

### (Development Processing)

In the present invention, development processing is conducted after exposing the silver salt-containing layer.

The developing method may be either of common chemical development and physical development, and the physical development may be a physical development in a narrow sense which involves a metal-supplying source on which silver or the like is to deposit or a solution physical development which does not involve a metal-supplying source but involves a solvent for a supplying source. In the invention, however, chemical development is most preferred in view of development activity on a latent image and, in the case of employing physical development, solution physical development is preferred.

As the chemical development processing, either of negative type development processing and reversal type development processing may be selected. The solution physical development may employ substantially the same composition except for the point that an agent for dissolving a metal compound which functions as a source for supplying a metal to deposit (a metal complex-forming agent, particularly a silver complex salt-forming agent) is incorporated.

The phrases of chemical development and physical development are used in the same meaning as is commonly used in the art, and are explained in general textbooks of photographic chemistry, for example, Shashin Kagaku (Photographic Chemistry) written by Shin-ichi Kikuchi (published by Kyoritsu Shuppan, 1955) and The Theory of Photographic Processes, 4^{th} ed. compiled by C. E. K. Mees, pp. 373-377 (published by Mcmillan, 1977).

A solution physical development solution has substantially the same composition as that of a chemically developing solution except for further containing a fixing agent component in a fixing solution in a content of from 0.002 to 1.0 mol/liter, preferably from 0.02 to 0.2 mol/liter. Since the compositions of the two solutions are not substantially different from each other except for this point, descriptions hereinafter are made by reference to the embodiment of chemical development.

In the development processing, common development processing techniques having been employed for silver salt photographic films, photographic printing papers, films for making printing plates, emulsion-coated layers for photo mask, and the like can be employed. As a developing solution, a black-and-white developing solution or a color developing solution (not necessarily forming a color) may be employed with no limitations as long as developed silver can be obtained. However, a black-and-white developing solution is preferred and, as the black-and-white developing solution, PQ developing solution, MQ developing solution, MAA developing solution (Metol/Ascorbic Acid developing solution), etc. can be used. For example, developing solutions of CN-16, CR-56, CP45X, FD-3 and PAPITOL having the formulations designated by Fuji Photo Film Co., Ltd., C-41, E-6, RA-4, D-72, etc. having the formulations designated by KODAK or developing solutions contained in the kits thereof, lith developing solutions known by the formulation names of D-19, D-85, D-8, etc. or contrasty positive developing solutions can be used as well.

In the embodiment of the aforesaid solution physical development, it suffices to add, as a silver halide-dissolving agent, a thiosulfate (e.g., sodium salt, ammonium salt, etc.) or a thiocyanate (e.g., sodium salt, ammonium salt, etc.) to each of the above-described developing solutions. It is preferred to add to a highly active developing solution such as D-19, D-85, D-8, D-72 or the like. With a physical development solution of a narrow sense, the same applies as with the embodiment of chemical development to be described hereinafter except for containing an object metal (e.g., copper) complex salt compound such as a silver complex salt in addition to the silver halide-dissolving agent which the solution physical development solution contains.

In the present invention, metal silver portions, preferably, pattern-shaped metal silver portions are formed, with simultaneously forming light-transmitting portions to be described hereinafter, by conducting the above-mentioned exposure and development processing.

The developing solution is required to have sufficient developing activity to completely reduce silver halide grains in exposed portions, i.e., silver halide grains having a latent image to metal silver. For this purpose, the solution preferably has an oxidation-reduction potential less noble than −290 mV vs SCE.

In this specification, oxidation-reduction potential of a developing solution means a potential measured by soaking an electrode into the developing solution and is an indicator of oxidation-reduction properties of the developing solution.

Specifically, it is a potential measured by soaking a platinum electrode (or an electrode of a non-erodable noble metal having substantial the same ionization tendency as platinum), and reading the potential the electrode indicates with reference to the saturated calomel electrode. The phrase “less noble than −290 mV vs SCE” as used herein means that the potential value which the electrode indicates is lower than −290 mV vs SCE, that is, the solution has higher activity.

In the production process of the present invention, an ascorbic acid series developing agent or a dihydroxybenzene series developing agent can be used in the developing solution. As the ascorbic acid series developing agent, there are illustrated ascorbic acid, isoascorbic acid, erisorbic acid or the salt thereof (Na salt or the like), with Na erisorbate being preferred in view of cost. As the dihydroxybenzene series developing agent, there are illustrated hydroquinone, chlorohydroquinone, isopropylhydroquinone, methylhydroquinone, hydroquinone monosulfonate, etc., with hydroquinone being particularly preferred. The ascorbic acid series developing agent or the dihydroxybenzene series developing agent may or many not be used in combination with an auxiliary developing agent particularly showing superadditivity. As the auxiliary developing agent showing superadditivity when used in combination with the ascorbic acid series developing agent or the dihydroxybenzene series developing agent, there are illustrated 1-phenyl-3-pyrazolidones and p-aminophenols.

As 1-phenyl-3-pyrazolidone or the derivatives thereof to be used as the auxiliary developing agent, there are specifically illustrated 1-phenyl-3-pyrazolidone, 1-phenyl-4,4-dimethyl-3-pyrazolidone, 1-phenyl-4-methyl-4-hydroxymethyl-3-pyrazolidone, etc.

As the p-aminophenol series auxiliary developing agent, there are illustrated N-methyl-p-aminophenol, p-aminophenol, N-(2-hydroxyethyl)-p-aminophenol, N-(4-hydroxyphenyl)glycine, etc. Of these, N-methyl-p-aminophenol is preferred.

The dihydroxybenzene series developing agent is usually used in an amount of preferably from 0.05 to 0.8 mol/liter and, in the present invention, it is particularly preferred to use it in an amount of 0.23 mol/liter or more. More preferably, it is used in an amount ranging from 0.23 to 0.6 mol/liter. In the case of using a combination of the dihydroxybenzene series developing agent and a 1-phenyl-3-pyrazolidone or a p-aminophenol, the former is used in an amount of preferably from 0.23 to 0.6 mol/liter, more preferably from 0.23 to 0.5 mol/liter, and the latter is used in an amount of preferably 0.06 mol/liter or less, more preferably from 0.03 mol/liter to 0.003 mol/liter.

In the present invention, both the initial developing solution and the development replenishing solution preferably have the properties of “undergoing an increase of pH by 0.5 or less when 0.1 mol of sodium hydroxide is added to 1 liter of the solution”. As a method for confirming that a initial developing solution and a development replenishing solution to be used have the properties, pH of the initial developing solution and the development replenishing solution to be tested is adjusted to 10.5, 0.1 mol of sodium hydroxide is added to 1 liter of each of them, the pH value after the addition is measured and, when the pH value is increased by 0.5 or less, the solutions are judged to have the above-specified properties. In the production process of the present invention, it is preferred to use a initial developing solution and a development replenishing solution each of which undergoes an increase in the pH value of 0.4 or less in the above-mentioned test.

As a method of imparting the above-mentioned properties to the initial developing solution and the development replenishing solution, a method of using a buffer agent is preferred. As the buffer agent, carbonates, boric acid described in JP-A-62-186259, sugars described in JP-A-60-93433 (e.g., saccharose), oximes (e.g., acetoxime), phenols (e.g., 5-sulfosalicylic acid), tertiary phosphates (e.g., sodium salt and potassium salt), etc. can be used, with carbonates and boric acid being preferably used. The amount of the buffer agent (particularly a carbonate) to be used is preferably 0.10 mol/liter or more, particularly preferably from 0.20 to 1.5 mols/liter.

In the present invention, pH of the initial developing solution is preferably from 9.0 to 11.0, particularly preferably from 9.5 to 10.7. The pH of the development replenishing solution and the pH of a developing solution within a developing tank upon continuous processing are also within this range. As an alkali agent to be used for adjusting the pH, common water-soluble inorganic alkali metal salts (e.g., sodium hydroxide, potassium hydroxide, sodium carbonate and potassium carbonate) can be used.

In the production process of the present invention, the content of a development replenishing solution in a developing solution upon processing 1 square meter of a light-sensitive material is 645 ml or less, preferably from 30 to 484 ml, particularly preferably from 100 to 484 ml. The development replenishing solution may have the same composition as that of the initial developing solution, or may contain a component which is to be consumed by development at a concentration higher than that of the initial developing solution.

The developing solution to be used in the present invention for development processing a light-sensitive material (hereinafter, in some cases, both the initial developing solution and the development replenishing solution are inclusively referred to merely as “developing solution”) may contain commonly used additives (e.g., a preservative and a chelating agent). As the preservative, there are illustrated sulfites such as sodium sulfite, potassium sulfite, lithium sulfite, ammonium sulfite, sodium bisulfite, potassium metabisulfite and formaldehyde sodium bisulfite. The sulfites are used in an amount of preferably 0.20 mol/liter or more, more preferably 0.3 mol/liter or more but, when added to much, they can cause silver stain, thus the upper limit being preferably 1.2 mols/liter. The amount is particularly preferably from 0.35 to 0.7 mol/liter. Also, as a preservative for a dihydroxybenzene series developing agent, a small amount of an ascorbic acid derivative may be used in combination with the sulfite. Such ascorbic acid derivative includes ascorbic acid, its stereoisomer of erisorbic acid, and alkali metal salts thereof (sodium salt and potassium salt). Use of sodium erisorbate as the ascorbic acid derivative is preferred in terms of material cost. The addition amount of the ascorbic acid derivative is in the range of preferably from 0.03 to 0.12, particularly preferably from 0.05 to 0.10, in terms of molar ratio based on the dihydroxybenzene series developing agent. In the case of using the ascorbic acid derivative as the preservative, it is preferred not to incorporate a boron compound in the developing solution.

As other additives than the above-described additives which can be used in the developing solution, development inhibitors such as sodium bromide and potassium bromide; organic solvents such as ethylene glycol, diethylene glycol, triethylene glycol and dimethylformamide; development accelerators such as alkanolamines (e.g., diethanolamine, triethanolamine, etc.), imidazole or the derivatives thereof, etc.; and anti-fogging agents or black pepper-preventing agents such as mercapto series compounds, indazole series compounds, benzotriazole series compounds and benzimidazole series compounds may be incorporated. As the benzimidazole series compounds, there can specifically be illustrated 5-nitroindazole, 5-p-nitrobenzoylaminoindazole, 1-methyl-5-nitroindazole, 6-nitroindazole, 3-methyl-5-nitroindazole, 5-nitrobenzimidazole, 2-isopropyl-5-benzimidazole, 5-nitrobenzotriazole, sodium 4-{(2-mercapto-1,3,4-thiadiazol-2-yl)thio}butanesulfonate, 5-amino-1,3,4-thiadiazole-2-thiol, methylbenzotriazole, 5-methylbenzotriazole, 2-mercaptobenzotriazole, etc. The contents of these benzimidazole series compounds are usually from 0.01 to 10 mmols, more preferably from 0.1 to 2 mmols, per liter of a developing solution.

Further, various organic or inorganic chelating agents may be used in the developing solution. As the inorganic chelating agents, sodium tetrapolyphosphate, sodium hexametaphosphate, etc. can be used. On the other hand, as the organic chelating agents, organic carboxylic acids, aminopolycarboxylic acids, organophosphoric acids, aminophosphoric acids and organic phosphonocarboxylic acids can mainly be used.

As the organic carboxylic acids, there can be illustrated acrylic acid, oxalic acid, malonic acid, succinic acid, glutaric acid, adipic acid, pimelic acid, succinic acid, azelaic acid, sebacic acid, nonanedicarboxylic acid, decanedicarboxylic acid, undecanedicarboxylic acid, maleic acid, itaconic acid, malic acid, citric acid, tartaric acid, etc. which, however, are not limitative at all.

As the aminopolycarboxylic acids, there can be illustrated iminodiacetic acid, nitrilotriacetic acid, nitrilotripropionic acid, ethylenediaminemonohydroxyethyltriacetic acid, ethylenediaminetetraacetic acid, glycol ether tetraacetic acid, 1,2-diaminopropanetetraacetic acid, diethylenetriaminepentaacetic acid, triethylenetetraminehexaacetic acid, 1,3-diamino-2-propanoltetraacetic acid, glycol ether diaminetetraacetic acid and, in addition, compounds described in JP-A-52-25632, JP-A-55-67747, JP-A-57-102624, JP-B-53-40900, etc.

The addition amount of the chelating agent is preferably from 1×10⁻⁴ to 1×10⁻¹ mol, more preferably from 1×10³ to 1×10⁻² mol, per liter of a developing solution.

Further, as silver stain-preventing agents, compounds described in JP-A-56-24347, JP-B-56-46585, JP-B-62-2849 and JP-A-4-362942 can be used in a developing solution. Still further, as dissolving aids, compounds described in JP-61-267759 can be used in a developing solution. Still further, the developing solution may contain, as needed, color-adjusting agents, surfactants, defoaming agents, hardeners, etc. The development processing temperature and time are related with each other, and are decided with respect to the total processing time. In general, however, the temperature is preferably from about 20° C. to about 50° C., more preferably from 25 to 45° C. Also, the developing time is preferably from 5 seconds to 2 minutes, more preferably from 7 seconds to 1 minute and 30 seconds.

For the purpose of reducing cost for transporting and wrapping a developing solution and saving space, an embodiment of concentrating and, upon use, diluting the developing solution to use is also preferred. In order to concentrate the developing solution, it is effective to change the salt component contained in the developing solution to potassium salt.

The development processing in the present invention may involve fixation processing which is conducted for the purpose of removing silver salt in unexposed portions to stabilize. For the fixation processing in the present invention, fixation processing technologies having been employed for color photographic films, black-and-white silver salt photographic films, photographic printing papers, films for making printing plates, X-ray photographic films, emulsion masks for photo masks, etc. can be employed.

The fixing step may be conducted subsequent to the developing step or after the physically developing step to be described hereinafter. Also, in the case of conducting solution physical development in at least any of the steps, the fixing step may be eliminated.

Preferred components for a fixing solution to be used in the fixing step include the following.

That is, sodium thiosulfate, ammonium thiosulfate and, as needed, tartaric acid, citric acid, gluconic acid, boric acid, iminodiacetic acid, 5-sulfosalicylic acid, glucoheptanoic acid, Tiron, ethylenediaminetetraacetic acid, diethylenetriaminepentaacetic acid, nitrilotriacetic acid or the salt thereof is preferably incorporated. From the standpoint of recent-year environmental protection, boric acid is not incorporated preferably. As a fixing agent in the fixing solution to be used in the present invention, sodium thiosulfate, ammonium thiosulfate, etc. are illustrated and, in view of fixing rate, ammonium thiosulfate is preferred. However, from the standpoint of recent-year environmental protection, sodium thiosulfate may be used as well. The amounts of these known fixing agents can properly be changed, but are generally from about 0.1 to about 2 mols/liter, particularly preferably from 0.2 to 1.5 mols/liter. The fixing solution may contain, as needed, a hardener (e.g., a water-soluble aluminum compound), a preservative (e.g., a sulfite or a bisulfite), a pH buffer (e.g., acetic acid), a pH-adjusting agent (e.g., ammonia or sulfuric acid), a chelating agent, a surfactant, a wetting agent and a fixation accelerator.

As the surfactant, there are illustrated, for example, anionic surfactants such as sulfates and sulfonates; polyethylene series surfactants; amphoteric surfactants described in JP-A-57-6740; etc. Known defoaming agents may be added to the fixing solution.

As the wetting agent, there are illustrated, for example, alkanolamine and alkylene glycol. Also, as the fixation accelerator, there are illustrated, for example, thiourea derivatives described in JP-B-45-35754, JP-B-58-122535 and JP-B-58-122536; alcohols having an intramolecular triple bond; thioether compounds described in U.S. Pat. No. 4,126,459; and mesoion compounds described in JP-A-4-229860. Compounds described in JP-A-2-44355 may also be used. As the pH buffer, organic acids such as acetic acid, malic acid, succinic acid, tartaric acid, citric acid, oxalic acid, maleic acid, glycolic acid and adipic acid; and inorganic buffers such as boric acid, phosphates and sulfites can be used. As the pH buffer, acetic acid, tartaric acid and sulfites are preferably used. Here, the pH buffers are used for the purpose of preventing an increase in pH of the fixing agent due to entrainment of the developing solution, and are used in amounts of preferably from about 0.01 to about 1.0 mol/liter, more preferably from about 0.02 to about 0.6 mol/liter. The pH of the fixing solution is preferably from 4.0 to 6.5, particularly preferably in the range of from 4.5 to 6.0. Also, compounds described in JP-A-64-4739 may be used as dye dissolution accelerators.

As the hardener in the fixing solution of the present invention, water-soluble aluminum salts and chromium salts are illustrated. Compounds preferred as the hardeners are water-soluble aluminum salts, and examples thereof include aluminum chloride, aluminum sulfate and potash alum. The addition amount of the hardener is preferably from 0.01 to 0.2 mol/liter, more preferably from 0.03 to 0.08 mol/liter.

The fixing temperature in the fixing step is preferably from about 20° C. to about 50° C., more preferably from 25 to 45° C. Also, the fixing time is preferably from 5 seconds to 1 minute, more preferably from 7 seconds to 50 seconds.

The light-sensitive material having been development processed and fixation processed is preferably subjected to water-washing processing and stabilization processing. In the water-washing processing or stabilization processing, the amount of washing water is usually 20 liters or less per m² of the light-sensitive material, and the processing may be conducted with a replenishing amount being 3 liters or less (including 0, i.e., washing in a reservoir) Therefore, water-saving processing becomes possible and, in addition, necessity of piping for installing an automatic developing machine can be eliminated. As a method for reducing the replenishing amount of washing water, a multi-stage countercurrent system (e.g., 2-stage, 3-stage or the like) has long been known. In the case of applying this multi-stage countercurrent system to the production process of the present invention, the fixed light-sensitive material is processed in an successively contact manner gradually in the normal direction, i.e., the direction toward a processing solution not stained with the fixing solution, thus washing being carried out with higher efficiency. Also, in the case of conducting the water-washing processing using a small amount of water, it is more preferred to provide a washing tank equipped with squeeze rollers and cross-over rollers described in JP-A-63-18350, JP-A-62-287252, etc. In order to reduce environmental load in the case of washing with a small amount of water, addition of various oxidizing agents or filtration through a filter may further be combined. Further, in the above-described process, part or the whole of overflow solution from a water-washing bath or stabilizing bath generated by replenishing the water-washing bath or stabilizing bath with water having anti-fungal means with the progress of processing can be utilized for a processing solution having fixing ability to be used in the preceding processing step as described in JP-A-60-235133. Also, a water-soluble surfactant or a defoaming agent may be added in order to prevent uneven bubble spots liable to generate upon washing with a small amount of water and/or to prevent processing agents adhering to squeeze rollers from being transferred to processed films.

Also, in the water-washing processing or stabilizing processing, dye-adsorbing agents described in JP-A-63-163456 may be provided in a water-washing tank in order to prevent stain with dyes having been dissolved out of the light-sensitive material. Further, in the stabilizing processing subsequent to the water-washing processing, a bath containing compounds described in JP-A-2-201357, JP-A-2-132435, JP-A-1-102553 and JP-A-46-44446 may be used as the final bath for a light-sensitive material. In this occasion, ammonium compounds, compounds of metals such as Bi and Al, fluorescent brightening agents, various chelating agents, film pH-adjusting agents, hardeners, bactericides, antifungal agents, alkanolamines and surfactants may be added, as needed. As water to be used in the water-washing step or the stabilizing step, deionized water or water having been sterilized with halogen, a UV ray sterilization lamp, various oxidizing agents (ozone, hydrogen peroxide, chlorates, etc.) or the like is preferably used as well as city water. In addition, washing water containing compounds described in JP-A-4-39652 and JP-A-5-241309 may also be used. The bath temperature and time in the water-washing processing or stabilizing washing are preferably from 0 to 50° C. and from 5 seconds to 2 minutes, respectively.

Processing solutions such as a developing solution and a fixing solution to be used in the present invention are preferably stored in a wrapping material having a low oxygen permeability described in JP-A-61-73147. In the case of reducing the replenishing amount, it is preferred to prevent evaporation or air-oxidation of the solution by reducing the contact area with air in a processing tank. Roller-conveying type automatic developing machines are described in U.S. Pat. Nos. 3,025,779, 3,545,971, etc. and are referred to merely as roller-conveying type processors in this specification. The roller-conveying type processor preferably comprises the four steps of development, fixation, water washing and drying. In the present invention, too, it is most preferred to follow the four steps though other steps (e.g., stopping step) are not necessarily eliminated. Also, the water-washing step may be replaced by the stabilizing step in the four steps.

The weight of metal silver contained in exposed portions after development processing is preferably 50% by weight or more, more preferably 80% by weight or more, based on the weight of silver contained in the exposed portions before exposure. When the weight of silver contained in the exposed portions is 50% by weight or more based on the weight of silver contained in the exposed portions before exposure, high electrical conductivity can be obtained, thus such weight being preferred.

In the present invention, gradation after development processing is not particularly limited, but is preferably more than 4.0. When gradation after development processing exceeds 4.0, electrical conductivity of the conductive metal portions can be enhanced with maintaining transparency of light-transmitting portions at a high level. As a means to increase gradation to a level of 4.0 or more, there is illustrated doping with rhodium ion or iridium ion having been described hereinbefore.

### (Physical Development)

In the present invention, physical development is performed after the developing step in order to deposit and add a metal (e.g., silver, or both silver and copper) onto the developed silver pattern obtained in the developing step.

“Physical development” as used herein in the present invention means to precipitate metal silver on the nuclei of a metal or a metal compound by reducing silver ion with a reducing agent. Physical development includes both physical development in a narrow sense wherein a metal-supplying source is incorporated in the processing solution and solution physical development wherein silver halide in a light-sensitive material is used as the metal-supplying source and no metal-supplying sources are incorporated in the processing solution. When the mesh-like pattern is subjected to physical development, metal silver is selectively precipitated onto the conductive metal silver, thus electrical conductivity being more enhanced.

A physical development solution in a narrow sense to be used in the present invention comprises a water-soluble silver complex salt-forming agent, a reducing agent and silver ion. Since a metal complex salt not derived from the light-sensitive material is obtained as a metal-supplying source, a metal pattern develops. On the other hand, solution physical development comprising a soluble silver complex salt-forming agent and a reducing agent may be employed as well. In this case, the silver-supplying source for supplying silver which is a metal to deposit is non-developed silver halide remaining after development, and hence the amount of supplied metal silver is limited. Since solution physical development does not contain any silver complex salt in the processing solution, the processing solution has a higher stability than with physical development in a narrow sense, thus being preferred.

As the soluble silver complex salt-forming agent, there are illustrated thiosulfates such as ammonium thiosulfate and sodium thiosulfate; thiocyanates such as sodium thiocyanate and ammonium thiocyanate; subsulfites such as sodium bisulfite and potassium bisulfite; oxazolidones; 2-mercaptobenzoic acid and the derivatives thereof; cyclic imides such as uracil; alkanolamines; diamines; mesoionic compounds described in JP-A-3-55528; thioethers as described in JP-B-47-11386; and compounds described in The theory of the photographic process, 4^{th} ed. (written by T. H. James, 1977), pp. 474-475.

As the soluble silver complex salt-forming agent, thiosulfates are preferred, with the concentration thereof being preferably from 0.0001 to 5 mol/L. In the present invention, a concentration of from 0.005 to 3 mol/L is particularly preferred, and a concentration of from 0.01 to 1 mol/L is still more preferred.

As the reducing agent, there are illustrated dihydroxybenzenes such as hydroquinone, chlorohydroquinone, isopropylhydroquinone, methylhydroquinone and hydroquinone monosulfonate; aminophenols such as p-aminophenol, 2,4-diaminophenol, N-methyl-p-aminophenol, N-(β-hydroxyethyl)-p-aminophenol and N-(4-hydroxyphenyl)glycine; ascorbic acid derivatives such as ascorbic acid, isoascorbic acid, erisorbic acid and salts thereof (Na salt, etc.); 1-phenyl-3-pyrazolidones such as 1-phenyl-3-pyrazolidone, 1-phenyl-4,4-dimethyl-3-pyrazolidone and 1-phenyl-4-methyl-4-hydroxymethyl-3-pyrazolidone; and the like. These may or may not be used in combination of two or more thereof.

The dihydroxybenzenes are used in an amount of from 0.05 to 0.8 mol/L, more preferably from 0.1 to 0.6 mol/L.

As silver ion, any silver salt containing mono-valent silver ion such as silver nitrate, silver halide or silver acetate that acts on the soluble silver complex salt-forming agent to dissolve in water can be used. The concentration of silver ion is preferably from 0.01 to 0.5 mol/L, more preferably from 0.03 to 0.3 mol/L.

### (Oxidation Processing)

In the production process of the present invention, the metal silver portions having been subjected to physical development processing is preferably subjected to oxidation processing. Oxidation processing can remove, when a metal slightly deposited on the light-transmitting portions, the metal to thereby make transparency of the light-transmitting portions almost 100%.

As the oxidation processing, there are illustrated known methods using various oxidizing agents, such as processing with Fe (III) ion. The oxidation processing can be conducted after exposure and development processing of a silver salt-containing layer.

In the present invention, the metal silver portions having been exposed and development processed may be processed with a solution containing Pd. Pd may be a di-valent palladium ion or metallic palladium. This processing serves to suppress blackening of the metal silver portions with time.

### (Conductive Metal Portions)

In the present invention, conductive metal portions are formed by more enhancing, through physical development, electrical conductivity of the conductive metal portions having been formed by the aforesaid exposure and development processing.

Metal silver is formed in exposed portions or in non-exposed portions. The silver salt diffusion transfer process (DTR process) utilizing physical development nuclei is a process of forming metal silver in non-exposed portions. In the present invention, metal silver is preferably formed in exposed portions in order to enhance transparency.

As conductive metal particles to be supported in the metal portions, there are illustrated particles of a metal such as copper, aluminum, nickel, iron, gold, cobalt, tin, stainless steel, tungsten, chromium, titanium, palladium, platinum, manganese, zinc or rhodium, or alloys of a combination thereof as well as silver described above. In view of electrical conductivity, silver and copper are preferred as the conductive metal particles. In the case of imparting magnetic field-shielding properties, it is preferred to use paramagnetic metal particles as the conductive metal particles

In order to enhance contrast in the conductive metal portions, the surface preferably has a black color, and silver generated by physical development is preferred due to its black color.

The weight of conductive metal portions after development is preferably 50% by weight or more, more preferably 60% by weight or more, based on the weight of the total silver contained in the conductive metal portions after physical development. When the weight of silver before physical development accounts for 50% by weight or more, the time required for physical development can be shortened, and productivity is improved to reduce production cost.

The conductive metal portions in the present invention have good electrical conductivity since conductive silver is further precipitated by physical development. The surface resistivity value of the conductive metal portions after physical development in the present invention is preferably 10³ Ω/sq or less, more preferably 2.5 Ω/sq or less, still more preferably 1.5 Ω/sq, most preferably 1.0 Ω/sq or less.

In the case of using as a light-transmitting electromagnetic wave-shielding material, the conductive metal portions of the present invention are preferably in a geometric pattern of a combination of a triangle such as an equilateral triangle, an isosceles triangle or a right triangle, a quadrilateral such as a square, a rectangle, a rhombus, a parallelogram or a trapezoid, a (regular) n-gon such as a (regular) hexagon or a (regular) octagon, a circle, an ellipse, a star, etc., more preferably in a mesh shape comprising these geometric pattern. In view of EMI-shielding properties, a triangular shape is most effective but, in view of light-transmitting properties, a (regular) n-gon with a larger n number provides a larger opening ratio when the line width is the same and provides larger visible light-transmitting properties, thus being advantageous.

Additionally, for the use as an conductive wiring material, the shape of the conductive metal portions is not particularly limited, and any shape may properly be selected according to the purpose.

In the use as light-transmitting electromagnetic wave-shielding material, the line width of the conductive metal portions is preferably 20 μm or less, and the line-to-line space is preferably 50 μm or more. Also, the conductive metal portions may have a part having a line width larger than 20 μm for the purpose of ground connection.

The opening ratio of the conductive metal portions in the invention is preferably 85% or more, more preferably 90% or more, most preferably 95% or more, in view of visible light transmittance. The opening ratio means a proportion of portions where mesh-forming fine wires do not exist versus the whole area. For example, the opening ratio of a square lattice mesh of 10 μm in line width and 200 μm in pitch is 90%.

### (Light-Transmitting Portions)

The phrase “light-transmitting portions” as used in the present invention means portions having transparent properties of the light-transmitting electromagnetic wave-shielding film other than the conductive metal portions. As has been described hereinbefore, the light transmittance of the light-transmitting portions is 90% or more, preferably 95% or more, more preferably 97% or more, still more preferably 98% or more, most preferably 99% or more, in terms of the minimum light transmittance in the wavelength region of from 380 to 780 nm with excluding contribution of light absorption and reflection by the support.

In view of improving light-transmitting properties, the light-transmitting portions of the present invention preferably have substantially no physical development nuclei. Since a soluble silver complex salt is precipitated onto physical development nuclei in the present invention, it is preferred for the light-transmitting portions to have substantially no physical development nuclei.

The phrase “to have substantially no physical development nuclei” as used herein means that the existence ratio of physical development nuclei in the light-transmitting portions is in the range of from 0 to 5%.

### (Layer Structure of a Light-Transmitting Electromagnetic Wave-Shielding Film)

The thickness of the support in the light-transmitting electromagnetic wave-shielding film of the present invention is preferably from 5 to 200 μm, more preferably from 30 to 150 μm. When the thickness is within the range of from 5 to 200 μm, a desired visible light transmittance and easy handling are obtained.

The thickness of the metal silver portions provided on the support before physical development can properly be determined according to the thickness of the coating composition for forming a silver salt-containing layer to be coated on the support. The thickness of the metal silver portions is preferably 30 μm or less, more preferably 20 μm or less. Also, the metal silver portions are in a pattern shape. The metal silver portions may have a one-layer structure or a multi-layer structure composed of two or more layers. In the case where the metal silver portions are in a pattern shape and have a multi-layer structure of two or more layers, different color sensitivities may be imparted so as to respond to lights with different wavelengths. This enables one to form different patterns in respective layers by changing the wavelength of exposing light. A light-transmitting conductive film containing the pattern-shaped metal silver portions of the multi-layer structure thus formed can be utilized as a high-density printed wiring board.

Regarding the thickness of the conductive metal portions, a smaller thickness serves to more enlarge the viewing angle of a display, thus being preferred for use as an electromagnetic wave-shielding material for a display. Further, for use as an conductive wiring material, reduction in thickness is required due to requirement for attaining high density wiring. From such standpoint, the thickness of a layer comprising conductive metal supported on the conductive metal portions is preferably less than 9 μm, more preferably from 0.1 μm to less than 7 μm.

In the present invention, conductive metal silver portions of a desired thickness can be formed by controlling the coating thickness of the above-mentioned silver salt-containing layer and, further, the thickness of a layer composed of conductive metal particles can be controlled by physical development. Thus, even a light-transmitting conductive film having a thickness less than 5 μm, preferably less than 3 μm can be formed with ease.

Additionally, while a conventional method of using etching has required removal and discarding of most part of a metal thin film by etching, a pattern containing only a necessary amount of conductive metal can be formed on a support in the present invention. Thus, use of only a necessary and minimal amount of metal is required, which is advantageous in view of two aspects of reduction in production cost and reduction in the amount of a metal waste.

(Functional Film Other than the Electromagnetic Wave-Shielding Film)

In the present invention, functional layers having desired functions may further be provided, as needed. Such functional layers may have various performances depending upon particular uses. For example, for use as an electromagnetic wave-shielding material for a display, an anti-reflection layer provided with an anti-reflective function by adjusting refractive index or film thickness; a non-glare layer or an anti-glare layer (both having the function of preventing dazzling; a near-infrared ray-absorbing layer comprising a compound or metal capable of absorbing near-infrared rays; a layer having the function of adjusting color tone which absorbs a visible light of a specific wavelength region; an anti-stain layer having the function of easily removing stains such as fingerprints; a difficulty scratchable hard coat layer; a layer having the function of absorbing impact; a layer having the function of preventing glass pieces from scattering upon breakage of glass; and the like can be provided. These functional layers may be provided on the opposite side to the silver salt-containing layer with the support being therebetween or may be provided on the same side.

These functional films may directly be stuck to PDP or may be stuck to a transparent substrate such as a glass plate or an acrylic resin plate separately from the plasma display panel itself. These functional films are called optical filters (or merely filters).

The anti-reflection layer provided with anti-reflective function can be formed by a method of forming a single layer or multi-layers of an inorganic material such as a metal oxide, fluoride, silicide, boride, carbide, nitride, sulfide or the like through a vacuum deposition method, sputtering method, ion-plating method, ion beam-assisting method or like method or by a method of forming a single layer or multi-layers of a resin having a different refractive index such as an acrylic resin or fluorine resin, in order to suppress reflection of external light and reduction of contrast. Also, a film having been subjected to anti-reflection-imparting processing can be stuck onto the filter. If necessary, a non-glare layer or an anti-glare layer may be provided. In the case of forming the non-glare layer or the anti-glare layer, there can be employed a method of formulating fine powder of silica, melamine, acryl or the like into an ink and coating it on the surface. For curing such ink, thermal curing or photo curing can be employed. It is also possible to stick the non-glare-processed or anti-glare-processed film onto the filter. Further, a hard coat layer may be provided, as needed.

As the near-infrared ray-absorbing layer, there can be illustrated a layer containing a near-infrared ray-absorbing dye such as a metal complex compound or a sputtered silver layer. Regarding the sputtered silver layer, lights of 1000 nm or longer in wavelength including infrared rays, deep-infrared rays and electromagnetic wave can be cut by alternately laminating a dielectric layer and a metal layer on a substrate through sputtering or the like. As dielectric substances to be incorporated in the dielectric layer, there are illustrated transparent metal oxides such as indium oxide and zinc oxide. As metals to be incorporated in the metal layer, silver or silver-palladium alloy is general. The sputtered silver layer usually initiates with a dielectric layer and has a laminated structure wherein about 3, 5, 7 or 11 layers are laminated.

Phosphors equipped in PDP and emitting a blue light have the characteristic property of slightly emitting a red light in addition to the blue light. Thus, there has been the problem that portions to be displayed in a blue color are displayed in a violetish color. The above-mentioned layer having color tone-adjusting ability and absorbing a visible light of a particular wavelength region is a layer to correct the color of emitted light as countermeasures for this problem and contains a dye capable of absorbing light of about 595 nm.

### (Volume Resistivity and Surface Resistivity)

The volume resistivity ratio is an electrical resistance per unit volume. The volume resistivity ratio is a physical quantity intrinsic to a substance, with the unit being Ωcm. In the present invention, the volume resistivity ratio of an conductive metal can be obtained by multiplying the surface resistivity measured according to the method described below by the thickness of the conductive layer.

The surface resistivity is an electrical resistance per unit area used in the field of coated films and thin films. The surface resistivity is a physical quantity intrinsic to each conductive film, with the unit being Ω/sq. In the present invention, the surface resistivity is obtained by measuring a light-transmitting conductive film having been processed and well dried. The measurement was conducted by employing the 4-pin probe method prescribed in JIS K 7194 “Method of measuring resistivity of conductive plastics according to 4-pin probe method”.

The surface resistivity is related with the electromagnetic wave-shielding properties and, the lower the resistance, the higher the electromagnetic wave-shielding properties. The surface resistivity value required for PDP depends upon intensity of electromagnetic wave radiated from the display itself, but the standard of FCC (Federal Communication Commission) in US or the technical standard of VCCI (Voluntary Control Council for Interference by Information Technology Equipment) in Japan prescribes that the surface resistivity value should be 2.5 Ω/sq or less for business use and 1.5 Ω/sq or less for consumer use.

### EXAMPLE 1

The present invention will be described more specifically by reference to Examples. Additionally, materials, amounts of used materials, proportions, contents of processing, processing orders, etc. do not limit the scope of the present invention unless they exceed the gist of the present invention, and are not to be construed as limitative based on the specific examples.

### (Silver Halide Light-Sensitive Material)

An emulsion containing 7.5 g of gelatin per 60 g of Ag in an aqueous medium and containing silver iodobromochloride grains (I=0.2 mol %; Br=50 mol %) of 0.1 μm in equivalent-sphere diameter was prepared. In this occasion, gelatin was properly added so that the volume ratio of Ag/gelatin became 1/0.6, 1/1 and 1/3 to prepare sample 1, sample 2 and sample 3, respectively.

To each emulsion were added K₃Rh₂Br₉ and K₂IrCl₆ so that the concentration became 10⁻⁷ (mol/mol silver) to dope the silver bromide grains with Rh ion and Ir ion. To the emulsion was added Na₂PdCL₄ and, further, gold-sulfur sensitization was conducted by using chloroauric acid and sodium thiosulfate. Then, the emulsion was coated on a polyethylene terephthalate (PET) support together with a gelatin hardener so that the coated amount of silver became 7 g/m². As the PET support, a PET support having previously been subjected to hydrophilicity-imparting treatment before coating was used.

The coating was conducted on a 30-cm wide PET support with a width of 25 cm for a length of 20 m, and both edges were cut off 3 cm so as to leave the 24-cm wide coated central portion to obtain a roll-shaped silver halide light-sensitive material.

### (Exposure)

Exposure was performed in a continuously exposing apparatus wherein exposing heads using DMD (Digital Mirror Device) described in an embodiment of the invention described in JP-A-2004-1244 were arranged in a width of 25 cm, the exposing heads and an exposing stage were disposed in a curved position so that a laser light can form an image on the light-sensitive layer of the light-sensitive material, a light-sensitive material-delivering mechanism and a light-sensitive material-winding mechanism are installed, and a bent portion is provided which exhibits buffer action so that variation of speed of tension-controlling mechanism for exposure surface and the delivering and winding mechanisms do not affect the speed of exposed portions. The wavelength of exposure light was 400 nm, the beam shape was approximately a square of 12 μm, and the irradiation amount of the laser light source was 100 μJ Exposure was conducted in a pattern wherein 12-μm pixels are arranged in a 45° lattice with a pitch of 300-μm interval in a continuous manner for a length of 10 m with a width of 24 cm.

### (Processing)

An exposed light-sensitive material was processed under the conditions that development was conducted at 35° C. for 30 seconds, fixation was conducted at 34° C. for 23 seconds, and water washing was conducted for 20 seconds with running water (SL/min) in an automatic developing machine FG-710PTS manufactured by Fuji Photo Film Co., Ltd. using the following processing agents, thus a slightly conductive silver image being obtained.

(Formulation of developing solution 1 L)

| | | |
|---|---|---|
| Hydroquinone | 20 | g |
| Sodium sulfite | 50 | g |
| Potassium carbonate | 40 | g |
| Ethylenediaminetetraacetic acid | 2 | g |
| Potassium bromide | 3 | g |
| Polyethylene glycol 2000 | 1 | g |
| Potassium hydroxide | 4 | g |

| | |
|---|---|
| pH | adjusted to 10.3 |

(Formulation of fixing solution 1 L)

| | | |
|---|---|---|
| Ammonium thiosulfate (75%) | 300 | ml |
| Ammonium thiosulfite monohydrate | 25 | g |
| 1,3-Diaminopropanetetraacetic acid | 8 | g |
| Acetic acid | 5 | g |
| Aqueous ammonia (27%) | 1 | g |

| | |
|---|---|
| pH | adjusted to 6.2 |

The slightly conductive, conductive film obtained by the development was subjected to physical development in the following physical development solution A containing a soluble silver-forming agent, a reducing agent and silver ion.

(Physical development solution (Formulation 1 L))

| | | |
|---|---|---|
| Silver nitrate | 15 | g |
| 2,4-Diaminophenol | 3 | g |
| Sodium sulfite | 100 | g |
| Sodium thiosulfate | 120 | g |
| Sodium tetraborate | 15 | g |

| | |
|---|---|
| pH | adjusted to 10.4 |

In preparing the developing solution, sodium sulfite and sodium thiosulfate were first dissolved, silver nitrate and 2,4-diaminophenol were added thereto and, after completely dissolving them, the alkali component is finally dissolved therein to adjust pH. The developing solution was used within 1 day after its preparation.

The processing was conducted at 30° C. till the surface resistivity reached 0.5 Ω/sq. The surface resistivity was measured by means of a flat 4-pin probe (ASP), LORESTA GP (Model MCP-T610) manufactured by Dia Instruments Co., Ltd.

### COMPARATIVE EXAMPLE 1

A silver halide light-sensitive material was prepared in the same manner as in Example 1, provided that the addition amount of gelatin was increased so as to make the silver-to-gelatin volume ratio 1/5. Additionally, when this sample was subjected to exposure, development and fixing processing in the same manner as in Example 1, no conductive properties were obtained after development.

This non-conductive film was subjected to the physical development in a narrow sense as in Example 1 till the surface resistivity reached 0.5 Ω/sq to thereby prepare sample 4.

### COMPARATIVE EXAMPLE 2

Sample 1 was used as a silver halide light-sensitive material and, after performing exposure in the same manner as in Example 1, was subjected to the same development, fixation and electroless plating as in Example 1 described in JP-A-2004-221564 to prepare sample 5 having the surface resistivity of 0.5 Ω/sq.

Colors of the thus-obtained light-transmitting conductive films in the mesh portions thereof after physical development or plating were visually evaluated. Samples with a black color were evaluated as “A”, and samples with other color than a black color as “B”. Further, they were left for 100 hours under the conditions of 60° C. in temperature and 90% in humidity, and those whose color did not change to yellow were visually evaluated as “A”, and those whose color changed were visually evaluated as “B”.

Results of the evaluation are shown in Table 1. Additionally, in the column of surface resistivity value in Table 1, the phrase “no electrical conductivity” means that, even after development, substantially no electrical conductivity was observed before physical development.

TABLE 1

| | Surface | | | | | |
|---|---|---|---|---|---|---|
| | resistivity | | | | | |
| | (Ω/sq) | | | | Ag/ | |
| | Before | | | Trans- | gelatin | |
| Sample | Physical | | Change | mittance | Volume | |
| No. | Development | Color | In Color | (%) | Ratio | Note |
| 1-1 | 1.5 | A | A | 90 | 1/0.6 | Present |
| | | | | | | Invention |
| 1-2 | 4 | A | A | 87 | 1/1 | Present |
| | | | | | | Invention |
| 1-3 | 100 | A | A | 83 | 1/3 | Present |
| | | | | | | Invention |
| 1-4 | no electrical | A | A | 76 | 1/5 | Compara- |
| | conductivity | | | | | tive |
| | | | | | | Example 1 |
| 1-5 | 1.5 | B | B | 90 | 1/0.6 | Compara- |
| | | | | | | tive |
| | | | | | | Example 2 |

As is apparent from Table 1, when physical development is conducted, the mesh portions acquires a black color as is different from case of the electroless copper plating, thus the effect of net reducing contrast of PDP being obtained. In addition, there is no change in color, and a highly durable light-transmitting conductive film can be obtained.

Further, in the present invention, since formalin is not used as is different from electroless copper plating, load on environment can be more reduced. Still further, in the present invention, since no mixed metals of silver and other metal are formed, recycling of the materials is facilitated.

Also, in comparison with Comparative Example 1, it is seen that transmittance can be increased by reducing the surface resistivity before physical development. This is attributed to the fact that reduction of the surface resistivity before physical development serves to shorten the time for physical development in a narrow sense, and that excess silver does not precipitate in the light-transmitting portions to thereby prevent reduction of transmittance.

### EXAMPLE 2

Silver halide light-sensitive materials of samples 1 to 3 described in Example 1 were used, and were subjected to exposure and development according to the same processing as described in Example 1 and, further, were subjected to solution physical development processing in the following physical development solution B containing a soluble silver-forming agent and a reducing agent. Thereafter, the fixation as in Example 1 was conducted to obtain conductive silver images.

(Formulation of physical development solution B 1 L)

| | | |
|---|---|---|
| Hydroquinone | 20 | g |
| 1-Phenyl-3-pyrazolidone | 5 | g |
| Sodium thiosulfite | 100 | g |
| Sodium thiosulfate | 10 | g |
| Sodium carbonate | 20 | g |

| | |
|---|---|
| pH | adjusted to 13.1 |

The processing was conducted at 30° C. till the surface resistivity reached 0.5 D/sq.

### COMPARATIVE EXAMPLE 3

A silver halide light-sensitive material of sample 4 of 1/5 in silver/gelatin volume ratio prepared in Comparative Example 1 was used, subjected to the same processing as in Example 2 till the surface resistivity reached 0.5 Ω/sq.

Colors of the thus-obtained light-transmitting conductive films in the mesh portions thereof after physical development or plating were visually evaluated. Samples with a black color were evaluated as “A”, and samples with other color than a black color as “B”. Further, they were left for 100 hours under the conditions of 60° C. in temperature and 90% in humidity, and those whose color did not change to yellow were visually evaluated as “A”, and those whose color changed were visually evaluated as “B”.

TABLE 2

| | | | Trans- | Ag/gelatin | |
|---|---|---|---|---|---|
| Sample | | Change In | mittance | Volume | |
| No. | Color | Color | (%) | Ratio | Note |
| 2-1 | A | A | 90 | 1/0.6 | Present |
| | | | | | Invention |
| 2-2 | A | A | 90 | 1/1 | Present |
| | | | | | Invention |
| 2-3 | A | A | 89 | 1/3 | Present |
| | | | | | Invention |
| 2-4 | A | A | 78 | 1/5 | Comparative |
| | | | | | Example 3 |
| 2-5 | B | B | 90 | 1/0.6 | Comparative |
| | | | | | Example 2 |

As in Example 1, when physical development is conducted, the mesh portions acquires a black color as is different from the case of the electroless copper plating, thus the effect of not reducing contrast of PDP being obtained. In addition, there is no change in color, and a highly durable light-transmitting conductive film can be obtained. Also, in comparison with Comparative Example 3, it is seen that transmittance can be increased by the larger Ag/gelatin volume ratio. From the results in Example 1, it is demonstrated that a larger Ag/gelatin volume ratio means a smaller surface resistivity before physical development. It is seen from this that the transmittance can be increased by reducing the surface resistivity before physical development. This is attributed to that reduction of the surface resistivity before physical development serves to shorten the time for solution physical development, and that excess silver does not precipitate in the light-transmitting portions to thereby prevent reduction of transmittance.

1-13. (canceled)

14. A light-transmitting conductive film comprising a transparent support having a 3-m or longer continuous mesh pattern including:
conductive metal portions comprising a conductive metal and having electrical conductivity; and
light-transmitting portions,
wherein
the conductive metal portions and light-transmitting portions are obtained by mesh pattern-wise exposing a silver halide light-sensitive material and subjecting to development processing, and then subjecting to physical development so as to more enhance the electrical conductivity.

15. The light-transmitting conductive film as claimed in claim 14, wherein the development processing is performed by using a developing solution having an oxidation-reduction potential less noble than −290 mV (vs SCE).

16. The light-transmitting conductive film as claimed in claim 14, wherein the conductive metal portions are formed in a mesh pattern of 20 μm or less in line width, the mesh pattern having the mesh opening ratio of 80% or more and the mesh surface resistivity of 5 Ω/sq or less.

17. The light-transmitting conductive film as claimed in claim 14, wherein the conductive metal portions are formed in a mesh pattern of 20 μm or less in line width, the mesh pattern having the mesh opening ratio of 80% or more and the mesh surface resistivity of 1 Ω/sq or less.

18. The light-transmitting conductive film as claimed in claim 14, wherein the conductive metal has a volume resistivity of 1.6 to 100 Ω·cm.

19. The light-transmitting conductive film as claimed in claim 14, wherein the silver halide light-sensitive material has volume ratio of a silver to a binder being 1/3 or more in a silver-containing layer provided on the transparent support.

20. The light-transmitting conductive film as claimed in claim 14, wherein the conductive metal portions are black.

21. A process for producing an light-transmitting conductive film, the process comprises:
exposing a silver halide light-sensitive material including a transparent support on which a silver halide light-sensitive layer is provided;
subjecting to development processing to form a 3-m or longer continuous mesh pattern including a conductive metal portions and visible light-transmitting portions; and
subjecting to physical development so as to more enhance electrical conductivity.

22. The process for producing the light-transmitting conductive film as claimed in claim 21, wherein the development processing is conducted using a developing solution having an oxidation-reduction potential less noble than −290 mV (vs SCE).

23. The process for producing the light-transmitting conductive film as claimed in claim 21, wherein the physical development is conducted in a solution of dissolution physical development containing a soluble silver complex salt-forming agent and a reducing agent.

24. The process for producing the light-transmitting conductive film as claimed in claim 21, wherein the physical development is conducted in a physically developing solution containing a soluble silver complex salt-forming agent, a reducing agent and silver ion.

25. The process for producing the light-transmitting conductive film as claimed in claim 21, wherein the soluble silver complex salt-forming agent comprises one of thiosulfate, thiocyanate and subsulfite.

26. The process for producing the light-transmitting conductive film as claimed in claim 21, wherein the soluble silver complex salt-forming agent comprises thiosulfate.

27. The process for producing the light-transmitting conductive film as claimed in claim 21, wherein the soluble silver complex salt-forming agent comprises sodium thiosulfate.

28. The process for producing the light-transmitting conductive film as claimed in claim 21, wherein the soluble silver complex salt-forming agent has molar concentration of 0.001 to 5 mol/L.

29. The process for producing the light-transmitting conductive film as claimed in claim 21, wherein the reducing agent comprises one of dihydroxybenzene, aminophenol, ascorbic acid derivative and 1-phenyl-3-pyrazolidone.

30. The process for producing the light-transmitting conductive film as claimed in claim 21, wherein the reducing agent has molar concentration of 0.05 to 0.8 mol/L.

31. A light-transmitting and electromagnetic wave-shielding film for a plasma display panel, which contains the light-transmitting conductive film according to claim 14, the light-transmitting conductive film having either shape of a roll shape and a sheet shape being cut from a roll.

32. A plasma display panel comprising the light-transmitting and electromagnetic wave-shielding film according to claim 31.
